(19) United States
(12) Patent Application Publication
(10) Pub. No.: US 2005/0127921 A1
(43) Pub. Date: Jun. 16, 2005

(54) Voltage detecting circuit

(76) Inventor: Masakazu Sugiura, Chiba-shi (JP)

Correspondence Address: ADAMS & WILKS;31ST FLOOR, 50 BROADWAY, NEW YORK, NY, 10004, US

(21) Appl. No.: 10/998,902

(22) Filed: Nov. 29, 2004

(30) Foreign Application Priority Data
Dec. 2, 2003 (JP) 2003-402789

(51) Int. Cl. G01R 31/08

(52) U.S. Cl. 324/522

(57) ABSTRACT

To provide a voltage detecting circuit, in which a leakage current of an output transistor is suppressed to reduce a consumed current without reducing a driving ability of the output transistor. The voltage detecting circuit is configured so as to control a voltage of a back gate of the output transistor in accordance with whether the voltage detecting circuit is in a detection state and in a release state.

### BACKGROUND OF THE INVENTTON

1. Field of the Invention

The present invention relates to a voltage detecting circuit for detecting a value of a voltage developed across detection terminals to change an output.

2. Description of the Related Art

FIG. 3 is a circuit block diagram of a voltage detecting circuit (refer to JP 2002-296306 A). Terminals which detect a voltage developed across them are connected to terminals 11 and 10, respectively. In case of the voltage detecting circuit shown in FIG. 3, terminals of a battery 1 are connected to the terminals 11 and 10, respectively. Voltage division resistors 13 and 14 are connected between the terminals 11 and 10. A node between the voltage division resistors 13 and 14, and a reference voltage source 15 are connected to inputs of a comparator 17. An output buffer circuit 18 is connected to an output of the comparator 17, and an output of the output buffer circuit 18 is connected to an output terminal 12. Illustration of power supply terminals of the comparator 17 is omitted in the drawing. In addition, it is supposed that the terminal 10 is given the GND electric potential.

The comparator 17 compares a voltage Va appearing at the node between the voltage division resistors 13 and 14 with a reference voltage Vb of the reference voltage source 15, thereby detecting a voltage of the battery 1. That is to say, a voltage at which an output of the comparator 17 is inverted is Va =Vb. In this example, the voltage Va changes due to a resistance ratio between the voltage division resistors 13 and 14, or due to the voltage of the battery 1. When a resistance value of the voltage division resistor 13 is assigned R1, a resistance value of the voltage division resistor 14 is assigned R2, and the voltage of the battery 1 is assigned V1, the detected voltage of the battery 1 is expressed by Equation (1):
Detected voltage=(R1+R2)/R2×Vb (1)

When the voltage of the battery 1 is higher than the voltage value expressed by Equation (1) (hereinafter, this state is referred to as “a release state”), the output of the comparator 17 goes to a high level, while when the voltage of the battery 1 is lower than the voltage value expressed by Equation (1) (hereinafter, this state is referred to as “a detection state”), the output of the comparator 17 goes to a low level. In other words, whether the voltage detecting circuit is in the release state or in the detection state can be known in correspondence to the output of the comparator 17 which is adapted to be at the high level or at the low level.

In general, since the voltage detecting circuit usually operates in order to detect an arbitrary voltage, a quantity of current consumed in the operation is desirably as small as possible. That is to say, a quantity of current consumed in the release state is desirably made as small as possible.

As shown in FIG. 4, the comparator 17 generally includes a current mirror circuit having P-channel MOS transistors 26 and 27, an input differential pair having N-channel MOS transistors 28 and 29, and a constant current circuit 30 for supplying a constant current I1.

In addition, as shown in FIG. 4, the output buffer circuit 18 includes an inverter 42, an output N-channel MOS transistor 43, and a pull-up resistor 40. In this example, the pull-up of the pull-up resistor 40 is carried out for a positive electrode of the battery 1. However, the pull-up of the pull-up resistor 40 may be carried out for a positive electrode of a second battery. In such cases, the voltage at the high level is determined based on the voltage of the second battery.

In order to reduce the consumed current in the release state in the conventional voltage detecting circuit, it is necessary to suppress a leakage current of the output N-channel MOS transistor, in other words, it is necessary to reduce a size of the output N-channel MOS transistor. However, if the size of the output N-channel MOS transistor is reduced, then there is encountered a problem that a SINK current driving ability in the detection state is reduced.

### SUMMARY OF THE INVENTION

In light of the foregoing, the present invention has been made in order to solve the above-mentioned problem associated with the prior art, and it is, therefore, an object of the present invention to provide a voltage detecting circuit which is capable of suppressing a leakage current to reduce a consumed current in a release state without reducing a SINK current driving ability in a detection state of an output N-channel MOS transistor.

A voltage detecting circuit of the present invention is configured so as to control a voltage of a back gate of an output transistor in accordance with whether the voltage detecting circuit is in a detection state and in a release state.

According to the voltage detecting circuit of the present invention, a leakage current of the output transistor can be suppressed to reduce a consumed current in the release state without reducing the SINK current driving ability of the output transistor.

### BRIEF DESCRIPTTON OF THE DRAWINGS

In the accompanying drawings:

FIG. 1 is a circuit block diagram of a voltage detecting circuit according to an embodiment of the present invention;

FIG. 2 is a circuit diagram of the voltage detecting circuit according to an embodiment of the present invention;

FIG. 3 is a circuit block diagram of a conventional voltage detecting circuit;

FIG. 4 is a circuit diagram of the conventional voltage detecting circuit; and

FIG. 5 is a circuit diagram of a voltage detecting circuit according to another embodiment of the present invention.

### DETAILED DESCRIPTION OF THE PREFERRED EMBODIMENTS

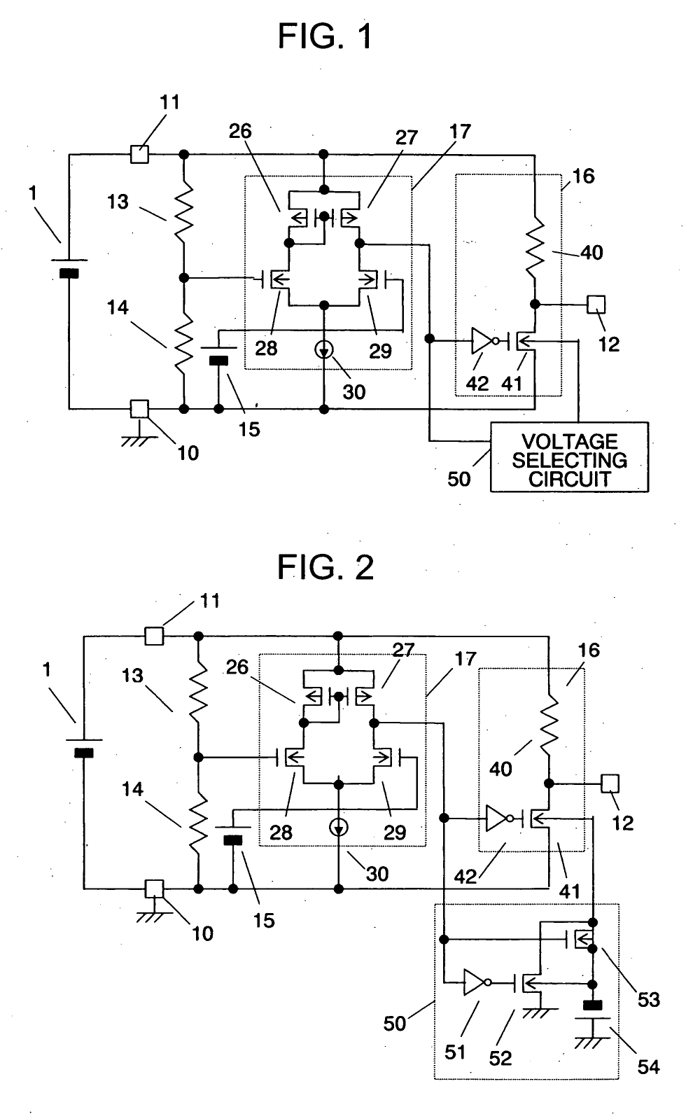

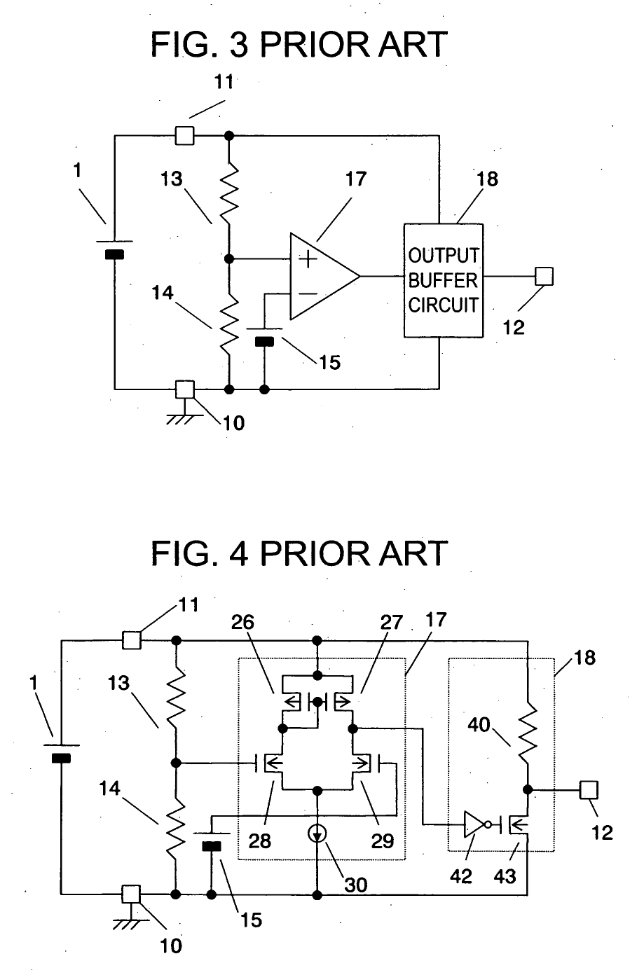

FIG. 1 is a circuit block diagram of a voltage detecting circuit according to a first embodiment of the present invention. An input of a voltage selecting circuit 50 is connected to an output of a comparator 17, and an output thereof is connected to a back gate of an output N-channel MOS transistor 41. The voltage selecting circuit 50 serves to reduce a back gate bias electric potential of the output N-channel MOS transistor 41 when the voltage detecting circuit is in a release state, and to increase the back gate bias electric potential of the output N-channel MOS transistor 41 when the voltage detecting circuit is in a detection state in accordance with an output from the comparator 17.

FIG. 2 shows a circuit diagram of the voltage selecting circuit 50. The voltage selecting circuit 50 includes an inverter 51, an N-channel MOS transistor 52, an N-channel MOS transistor 53, and a battery 54.

When the voltage detecting circuit is in the release state, in the voltage selecting circuit 50, since an input of the inverter 51 is at a high level, the N-channel MOS transistor 52 is turned OFF and the N-channel MOS transistor 53 is turned ON.

Now, when it is supposed that a voltage of the battery 54 is assigned V54, the back gate bias electric potential of the output N-channel MOS transistor 41 is given as a negative value, i.e., −V54.

On the other hand, when the voltage detecting circuit is in the detection state, in the voltage selecting circuit 50, since the input of the inverter 51 is at a low level, the N-channel MOS transistor 52 is turned ON and the N-channel MOS transistor 53 is turned OFF. Consequently, the back gate bias electric potential of the output N-channel MOS transistor 41 is given as the GND electric potential.

As described above, the voltage selecting circuit 50 controls the back gate bias electric potential of the output N-channel MOS transistor 41 so that the back gate bias electric potential when the voltage detecting circuit is in the release state becomes lower than that when the voltage detecting circuit is in the detection state. Hence, a threshold voltage of the output N-channel MOS transistor 41 in the case of the release state becomes higher than that in the case of the detection state. Consequently, a leakage current in the release state can be suppressed to a low level, i.e., a consumed current can be reduced without reducing a SINK current driving ability of the output N-channel MOS transistor 41 in the detection state.

In the above description, the voltage selecting circuit 50 has been explained as having the circuit configuration shown in FIG. 2. However, in case as well of any other circuit configuration having such a function that an output voltage value changes in accordance with a change in input signal, the same effects can be obtained.

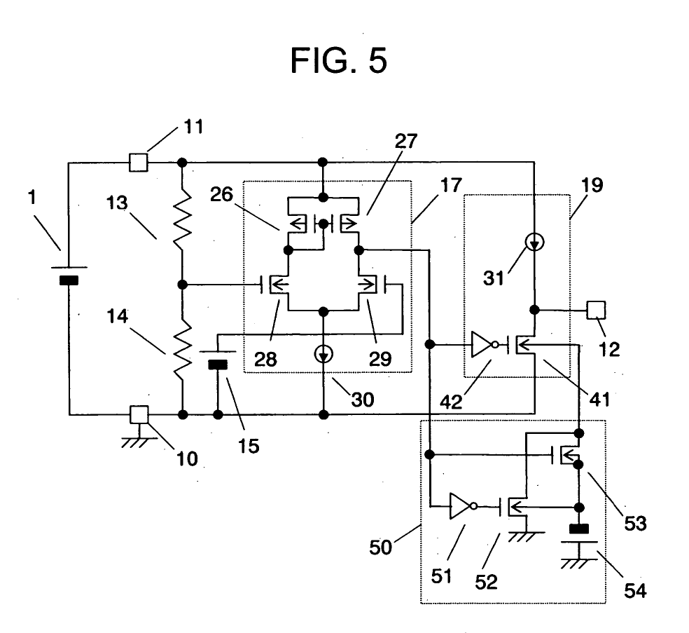

In addition, while the output buffer circuit 16 has been described as having the circuit configuration shown in FIG. 2, for example, in case as well of a circuit configuration as shown in FIG. 5, the same effects can be obtained. In an output buffer circuit 19 of a voltage detecting circuit shown in FIG. 5, a constant current circuit 31 is provided instead of a pull-up resistor 40 in the output buffer circuit 16 of the voltage detecting circuit shown in FIG. 2.

1. A voltage detecting circuit comprising an output transistor, wherein a threshold voltage of the output transistor is changed in accordance with whether the voltage detecting circuit is in a release state or in a detection state.

2. A voltage detecting circuit according to claim 1, wherein a voltage of a back gate bias of the output transistor is changed to change the threshold voltage of the output transistor.

3. A voltage detecting circuit, comprising:
a comparator for detecting a predetermined voltage to invert its output;
an output transistor connected to an output of the comparator; and
a voltage selecting circuit connected to the output of the comparator,
wherein a voltage of a back gate bias of the output transistor is changed in accordance with an output from the voltage selecting circuit.

4. A voltage detecting circuit according to claim 3, wherein the output transistor is an N-channel MOS transistor, the voltage selecting circuit includes: a second N-channel MOS transistor having a gate connected to the output of the comparator and a source connected to a second power supply; and a third N-channel MOS transistor having a gate connected to the output of the comparator through an inverter, and drains of the second N-channel MOS transistor and the third N-channel MOS transistor are connected to a back gate of the output transistor.
